(19) United States
(12) Patent Application Publication
(10) Pub. No.: US 2009/0059482 A1
(43) Pub. Date: Mar. 5, 2009

(54) ELECTRONIC DEVICE

(75) Inventors: Chih-Chiang Hsu, Tao Yuan Shien (TW); Tsung-Ju Chiang, Tao Yuan Shien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: QUANTA COMPUTER INC., Tao Yuan Shien (TW)

(21) Appl. No.: 11/969,933

(22) Filed: Jan. 7, 2008

(30) Foreign Application Priority Data
Sep. 4, 2007 (TW) 96214779

(51) Int. Cl. H05K 5/02

(52) U.S. Cl. 361/679

(57) ABSTRACT

An electronic device comprises a battery and a main body. The battery comprises an engaging element. The engaging element comprises a hook, a depressed surface and an inclined surface. The hook protrudes from the battery. The inclined surface and the depressed surface are connected to two sides of the hook. The main body comprises a linkage. The linkage is slidably disposed on the main body. The linkage comprises a hole with two side walls. The hook is engaged with the hole.

### BACKGROUND OF THE INVENTION

1. Field of the Invention

The invention relates to an electronic device, and more particularly to an electronic device with a battery.

2. Description of the Related Art

Present electronic devices are usually assembled with a rechargeable battery to provide power. Thus, a user must assemble and disassemble the battery. For example, for a notebook computer, two buttons are installed on a conventional notebook for disassembling the battery. Thus, a user uses both hands to control the buttons. After pressing the buttons, a user must manually take the battery from the notebook. It is inconvenient for a user to disassemble the battery.

### BRIEF SUMMARY OF INVENTION

A detailed description is given in the following embodiments with reference to the accompanying drawings. The invention provides an electronic device. The electronic device comprises a battery and a main body. The battery comprises an engaging element. The engaging element comprises a hook, a depressed surface and an inclined surface. The hook protrudes from the battery. The inclined surface and the depressed surface are respectively disposed on two sides of the hook. The main body comprises a linkage. The linkage is slidably disposed on the main body. The linkage comprises a hole. The hole comprises two side walls. The hook is engaged with the hole. When the battery and the main body are in a fixed state, one of the side walls of the hole is pushed toward the depressed surface and the hook is engaged with one of the side walls. When the battery and the main body are in a detached state, the other side wall of the hole is pushed and moves toward the inclined surface to detach the battery from the main body.

### BRIEF DESCRIPTION OF DRAWINGS

The invention can be more fully understood by reading the subsequent detailed description and examples with references made to the accompanying drawings, wherein:

FIG. 1 is an exploded view of an electronic device and a battery according to the invention;

FIG. 2 is a schematic view of a linkage according to the invention;

FIG. 3 is a schematic view showing the assembly of a battery in an electronic device according to the invention;

FIGS. 4 to 6 are schematic views showing the process of a battery being released from an electronic device according to the invention.

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

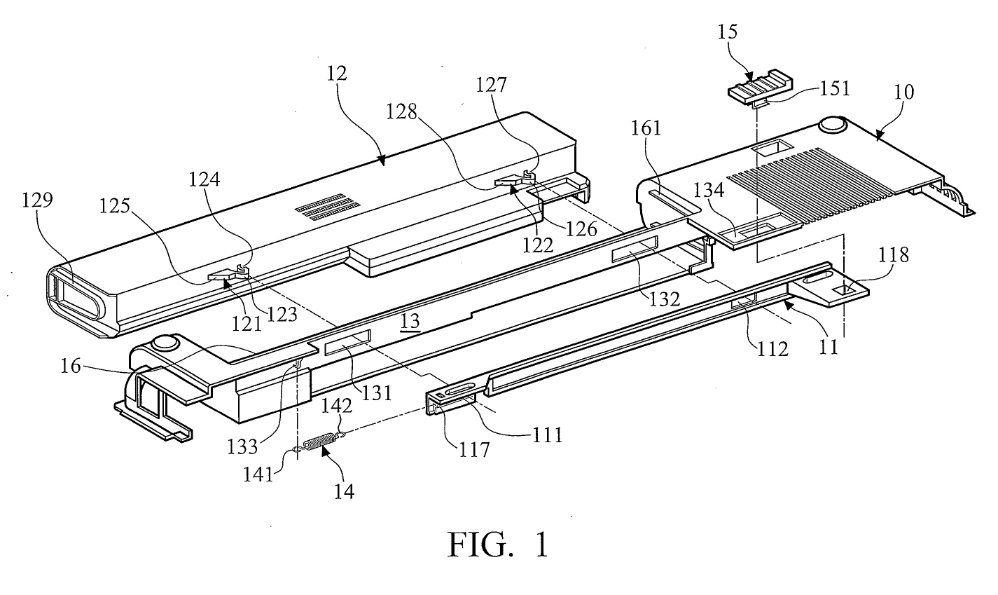

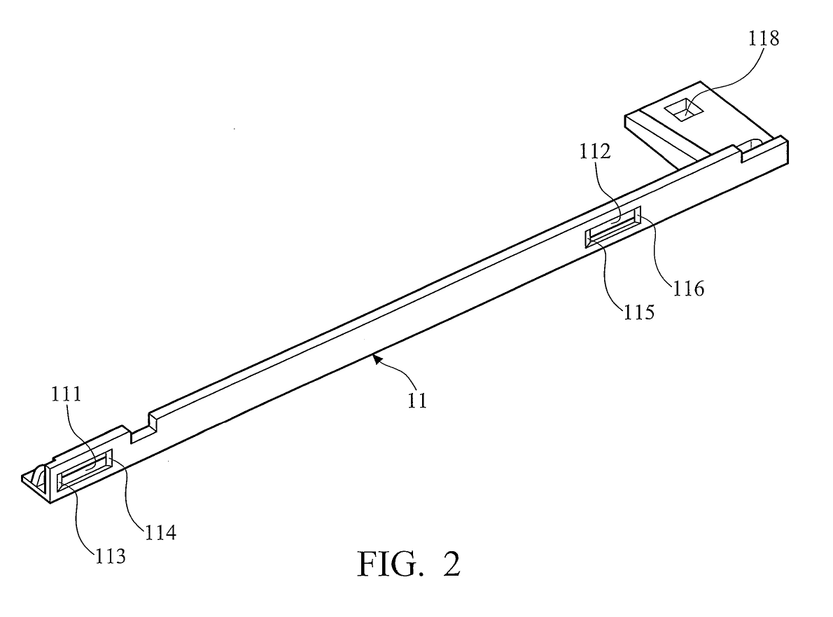

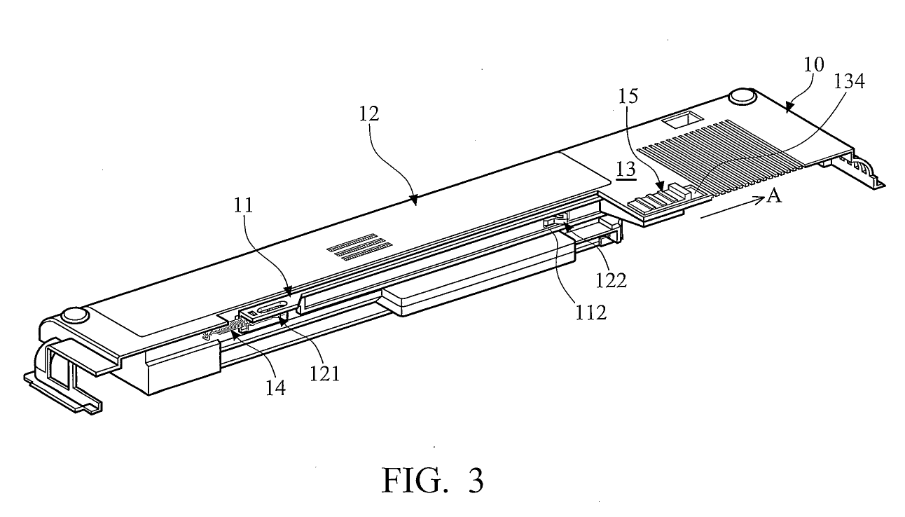

Referring to FIGS. 1, 2 and 3, FIG. 1 is an exploded view of an electronic device 10 and a battery 12, FIG. 2 is a schematic view of a linkage 11, and FIG. 3 is a schematic view showing the assembly of a battery 12 in an electronic device 10, all, according to the invention. An electronic device 10, for example a notebook computer, the electronic device 10 comprises a linkage 11, a shell 13 and an elastic 14. The linkage 11 is movably disposed on the electronic device 10. The linkage 11 comprises two holes 111 and 112. The holes 111 and 112 comprise four side walls 113, 114, 115 and 116 (shown in FIG. 2). The battery 12 comprises two engaging elements 121 and 122. The engaging elements 121 and 122 comprise hooks 123 and 126, depressed surfaces 124 and 127, and inclined surfaces 125 and 128. The hooks 123 and 124 protrude from the battery 12. The inclined surfaces 125 and 128, and the depressed surfaces 124 and 127 are disposed on two sides of the hooks 123 and 126. The hooks 123 and 126 are installed in the holes 111 and 112. The shell 13 comprises two openings 131 and 132. The hooks 123 and 126 pass through the openings 131 and 132 and then pass through the holes 111 and 112 of the linkage 11.

In this embodiment, the shell 13 of the electronic device 10 further comprises a first fixing element 133. The linkage 11 comprises a second fixing element 117. Two ends of the elastic element 14 comprise hangers 141 and 142. The elastic element 14 is connected to the first fixing element 133 via the hanger 141. The elastic element 14 is connected to the second fixing element 117 via the hanger 142. Thus, when the linkage 11 moves corresponding to the electronic 10, resilience is generated. The electronic device 10 further comprises a button 15. The button 15 comprises a tenon 151 on the bottom of the button 15. The shell 13 of the electronic device 10 comprises an accommodating portion 134. The linkage 11 comprises a connector 118. The connector 118 is a hole. The tenon 151 on the bottom of the button 15 passes through the accommodating portion 134 and then is fixed to the connector 118. Thus, a user presses the button 15 to drive the linkage 11 for pushing the battery 12. Note that the size of the accommodating portion 134 is greater than that of the button 15. The button 15 slides in the accommodating portion 134 for moving the linkage 11.

The electronic device 10 comprises a battery chamber 16 for containing the battery 12. Two sides of the battery chamber 16 comprise a first guiding portion 161. Two sides of the battery 12 comprise a second guiding portion 129 corresponding to the first guiding portion 161. The battery 12 slides into the battery chamber 16 via the first guiding portion 161 and the second guiding portion 129. In this embodiment, the angle of the inclined surfaces 125 and 128 are less than or equal to 45 degrees. The side walls 113 and 115 to connect to the inclined surfaces 125 and 128 and are inclined. The side walls 113 and 115 slope corresponding to the inclined surfaces 125 and 128.

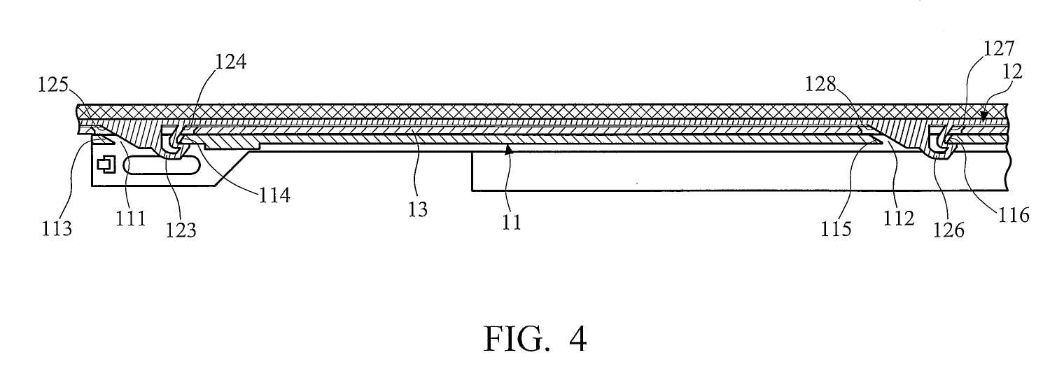

Referring to FIGS. 4 to 6, FIGS. 4 to 6 are schematic views showing the process of a battery 12 being released from an electronic device 10 according to the invention. When the battery 12 is fixed to the electronic device 10 (shown in FIG. 4), the side walls 114 and 116 of the holes 111 and 112 of the linkage 11 are engaged with the depressed surfaces 124 and 127, and fixed to the hooks 123 and 126.

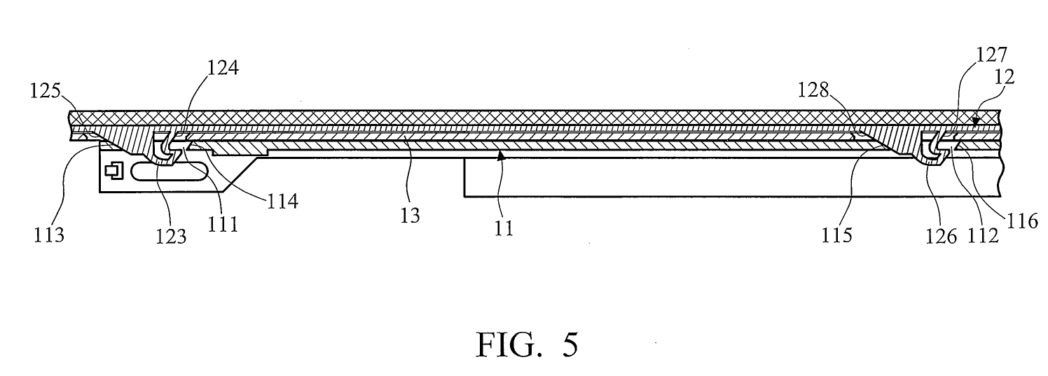

Referring to FIG. 3, if a user releases the battery 12, the button 15 is pushed along arrow A. Because the button 15 is connected to the linkage 11, the button 15 drives the linkage 11 to move along arrow A. The side walls 114 and 116 of the holes 111 and 112 are separated from the depressed surfaces 124 and 127. The other side walls 113 and 115 of the holes 111 and 112 approach the inclined surfaces 125 and 128, as shown in FIG. 5.

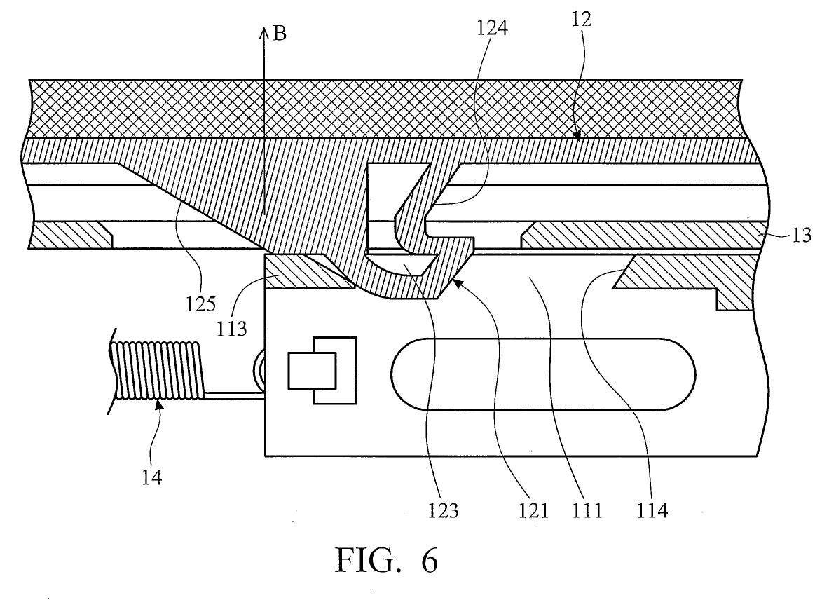

Referring to FIGS. 3 and 6, FIG. 6 only shows the hook 123 and hole 111 on one side of the electronic device 10 and the battery 12. When the button 15 continues to move along arrow A, the side wall 113 slides along the inclined surface 125. Thus, the battery 12 generates vertical displacement corresponding to the linkage 11 and the battery 12 is pushed along arrow B. The hook 126 moves the same as the hook 123, thus, repeated description is omitted for brevity. The elastic 14 is installed in the electronic device 10. After taking the battery 12 out, the linkage 11 automatically bounces back to the position as shown in FIG. 4. When assembling the battery 12 on the electronic device 10, a user directly pushes the battery 12 into the battery chamber 16. The fixing elements 121 and 122 of the battery 12 pushes off of the linkage 11. Thus, the linkage 11 laterally moves until the side walls 114 and 116 are engaged with the depressed surfaces 124 and 127 and the side walls 114 and 116 are fixed to the hooks 123 and 126, as also shown in FIG. 1.

The electronic device 10 of the invention provides easier usage for users. When taking off the battery 12, a user only need to press the button 15 and then the battery 12 is detached from the electronic device 10 via the design mechanism of the invention. Thus, a user only uses one hand to assemble and disassemble the battery 12.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. An electronic device, comprising:
a battery comprising at least an engaging element, and the engaging element comprising a hook, a depressed surface and an inclined surface, wherein the hook protrudes from the battery, and the inclined surface and the depressed surface are respectively disposed on two sides of the hook; and
a main body comprising a linkage, wherein the linkage is slidably disposed on the main body, the linkage comprises at least a hole, the hole comprises two side walls, and the hook is engaged with the hole;
wherein when the battery and the main body are in a fixed state, one of the side walls of the hole is pushed toward the depressed surface and the hook is engaged with one of the side walls, and
when the battery and the main body are in a detached state, the other side wall of the hole is pushed and moves toward the inclined surface to detach the battery from the main body.

2. The electronic device as claimed in claim 1, wherein the main body further comprises a shell, and the battery and the linkage are respectively disposed two sides of the shell.

3. The electronic device as claimed in claim 2, wherein the shell comprises an opening, and the hook passes through the opening and the hole of the linkage.

4. The electronic device as claimed in claim 1, wherein the main body further comprises an elastic element connected to the main body and the linkage.

5. The electronic device claimed in claim 4, wherein the main body further comprises a first fixing element, the linkage comprises a second fixing element, and two ends of the elastic element are respectively connected to the first fixing element and the second fixing element.

6. The electronic device claimed in claim 1, wherein the main body comprises a button and an accommodating portion, the linkage comprises a connector, and the button is installed in the accommodating portion and connected to the connector.

7. The electronic device claimed in claim 6, wherein the size of the accommodating portion is greater than that of the button.

8. The electronic device as claimed in claim 1, wherein the main body further comprises a battery chamber for containing the battery.

9. The electronic device as claimed in claim 8, wherein the battery chamber comprises a first guiding portion on two sides of the battery chamber, the battery comprises a second guiding portion on two sides of the battery, and the battery slides into the battery chamber via the first guiding portion and the second guiding portion.

10. The electronic device as claimed in claim 1, wherein the angle of the inclined surface is less than 45 degrees.

11. The electronic device as claimed in claim 1, wherein the angle of the inclined surface is equal to 45 degrees.

12. The electronic device as claimed in claim 1, wherein the side wall of the hole to connect to the inclined surface is inclined, and the side wall slopes correspond to the inclined surface.
